(19) United States
(12) Patent Application Publication
(10) Pub. No.: US 2024/0213937 A1
(43) Pub. Date: Jun. 27, 2024

(54) RADIO FREQUENCY CIRCUIT

(71) Applicant: Murata Manufacturing Co., Ltd., Kyoto (JP)

(72) Inventor: Ikumi TOKUDA, Kyoto (JP)

(21) Appl. No.: 18/594,443

(22) Filed: Mar. 4, 2024

Related U.S. Application Data
(63) Continuation of application No. PCT/JP2022/031436, filed on Aug. 19, 2022.

(30) Foreign Application Priority Data
Sep. 7, 2021 (JP) 2021-145520

(51) Int. Cl. H03F 3/24; H03F 1/56

(52) U.S. Cl. CPC H03F 3/245; H03F 1/56; H03F 2200/222

(57) ABSTRACT

A radio frequency circuit includes a first circuit including a radio frequency input terminal, a radio frequency output terminal, and a control terminal, a power detector connected to the radio frequency output terminal, a correction circuit including a clock terminal, an enable terminal, an input terminal, and an output terminal, a first comparator connected between an output of the power detector and the clock terminal, and a second comparator connected between the output of the power detector and the enable terminal. The output terminal is connected to the control terminal. A reference voltage of the second comparator is higher than that of the first comparator.

### CROSS REFERENCE TO RELATED APPLICATION

This is a continuation of International Application No. PCT/JP2022/031436 filed on Aug. 19, 2022, which claims priority from Japanese Patent Application No. 2021-145520 filed on Sep. 7, 2021. The contents of these applications are incorporated herein by reference in their entireties.

### BACKGROUND ART

### Technical Field

The present disclosure relates to a radio frequency circuit.

Patent Document 1 discloses an amplifier including a transistor for amplifying a signal, a voltage detection unit, a compensation determination circuit, and a gain compensation circuit. In the amplifier disclosed in Patent Document 1, the voltage detection unit detects a current flowing through the drain terminal of a transistor as a potential difference by voltage conversion. The compensation determination circuit determines whether gain compensation is performed on the basis of a potential difference detected by the voltage detection unit. When it is determined that gain compensation is performed, the gain compensation circuit performs gain compensation in accordance with a potential difference detected by the voltage detection unit.

Patent Document 1: Japanese Patent No. 5267321

### BRIEF SUMMARY

However, the above-described amplifier in the related art cannot sufficiently perform gain compensation in some cases, such as not being able to compensate for a load change. In a radio frequency circuit for processing radio frequency signals, not only gain compensation but also further improvement of performance is required.

The present disclosure provides a high-performance radio frequency circuit.

A radio frequency circuit according to an aspect of the present disclosure includes a first circuit including a radio frequency input terminal, a radio frequency output terminal, and a control terminal, a power detector connected to the radio frequency output terminal, a correction circuit including a clock terminal, an enable terminal, an input terminal, and an output terminal, a first comparator connected between an output of the power detector and the clock terminal, and a second comparator connected between an output of the power detector and the enable terminal. The output terminal is connected to the control terminal. A reference voltage of the second comparator is higher than that of the first comparator.

A radio frequency circuit according to another aspect of the present disclosure includes a first circuit configured to process a radio frequency signal, a power detector configured to detect power of a radio frequency signal, a first comparator configured to compare a voltage representing a detection result of the power detector and a first reference voltage with each other, a second comparator configured to compare a voltage representing a detection result of the power detector and a second reference voltage higher than the first reference voltage with each other, and a correction circuit configured to perform correction upon the first circuit based on a comparison result of the first comparator and a comparison result of the second comparator.

According to the present disclosure, there can be provided a high-performance radio frequency circuit.

### BRIEF DESCRIPTION OF THE DRAWINGS

FIG. 1 is a diagram illustrating the configuration of a communication device according to an embodiment.

FIG. 2 is a diagram illustrating the circuit configuration of a radio frequency circuit according to an embodiment.

FIG. 3 is a diagram illustrating a radio frequency signal that a radio frequency circuit according to an embodiment processes and two reference voltages.

FIG. 4A is a diagram for the description of a problem when the number of reference voltages is one.

FIG. 4B is a diagram for the description of another problem when the number of reference voltages is one.

FIG. 5 is a diagram illustrating the circuit configuration of a radio frequency circuit according to a first modification.

FIG. 6 is a diagram illustrating the circuit configuration of a radio frequency circuit according to a second modification.

FIG. 7A is a diagram illustrating the circuit configuration of a radio frequency circuit according to a third modification.

FIG. 7B is a diagram illustrating the circuit configuration of another example of a radio frequency circuit according to the third modification.

FIG. 8 is a diagram illustrating the circuit configuration of a radio frequency circuit according to a fourth modification.

### DETAILED DESCRIPTION

A radio frequency circuit according to an embodiment of the present disclosure will be described in detail below with reference to drawings. The embodiment to be described below illustrates a specific example of the present disclosure. Accordingly, the numerical values, shapes, materials, constituent elements, arrangements of the constituent elements, the ways in which the constituent elements are connected, steps, the order of the steps, and so forth described in the following embodiment are merely examples and are not intended to limit the present disclosure. Accordingly, constituent elements not described in the independent claims among constituent elements in the following embodiment are described as optional constituent elements.

The drawings are schematic drawings and are not necessarily illustrated in a strictly accurate manner. Accordingly, for example, the scales and so forth in the respective drawings are not necessarily the same. Furthermore, in the drawings, configurations that are substantially the same as each other are denoted by the same symbols and repeated description thereof is omitted or simplified.

In this specification, the meaning of “connected” includes not only directly connected with connection terminals and/or wiring conductors, but also electrical connections established via other circuit elements. Furthermore, “connected between A and B” means connected to both A and B between A and B.

In this specification, ordinal numbers, such as “first” and “second” do not mean the number or order of constituent elements unless otherwise stated, and rather are used for the purpose of avoiding confusion and distinguishing between constituent elements of the same type.

In this specification, a “transmission path” means a transmission line including, for example, a wiring line for transmitting a radio frequency transmission signal, an electrode directly connected to the wiring line, and a terminal directly connected to the wiring line or the electrode. A “reception path” means a transmission line including, for example, a wiring line for transmitting a radio frequency reception signal, an electrode directly connected to the wiring line, and a terminal directly connected to the wiring line or the electrode. A “transmission/reception path” means a transmission line including, for example, a wiring line for transmitting both a radio frequency transmission signal and a radio frequency reception signal, an electrode directly connected to the wiring line, and a terminal directly connected to the wiring line or the electrode.

### Embodiment

### 1. Configuration of Communication Device 5

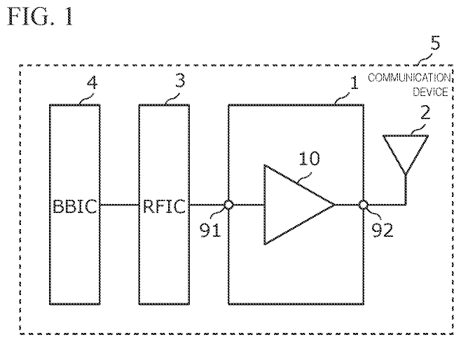

First, the configuration of the communication device 5 according to an embodiment will be described with reference to FIG. 1. FIG. 1 is a diagram illustrating the configuration of the communication device 5 according to the present embodiment.

The communication device 5 illustrated in FIG. 1 is a device used in a communication system and is, for example, a mobile terminal, such as a smartphone or a tablet computer. As illustrated in FIG. 1, the communication device 5 includes a radio frequency circuit 1, an antenna 2, an RFIC (radio frequency integrated circuit) 3, and a BBIC (baseband integrated circuit) 4.

The radio frequency circuit 1 transmits a radio frequency signal between the antenna 2 and the RFIC 3. The radio frequency circuit 1 includes an external input terminal 91 and an external output terminal 92. The radio frequency circuit 1 includes a power amplifier 10 for amplifying a transmission signal that is an example of a radio frequency signal.

The external input terminal 91 is a terminal for receiving a transmission signal from the outside of the radio frequency circuit 1. The external input terminal 91 is connected to the power amplifier 10 in the radio frequency circuit 1 and is connected to the RFIC 3 outside the radio frequency circuit 1. A transmission signal received from the RFIC 3 via the external input terminal 91 is therefore supplied to the power amplifier 10.

The external output terminal 92 is connected to the power amplifier 10 in the radio frequency circuit 1 and is connected to the antenna 2 outside the radio frequency circuit 1. The external output terminal 92 is also referred to as an antenna connection terminal. A transmission signal amplified by the power amplifier 10 is output to the antenna 2 via the external output terminal 92.

The radio frequency circuit 1 transmits a transmission signal in the present embodiment, but may transmit a reception signal that is an example of a radio frequency signal. That is, the radio frequency circuit 1 may include a transmission circuit for transmitting a transmission signal and a reception circuit for transmitting a reception signal. The radio frequency circuit 1 may include, for example, a low-noise amplifier (LNA) for amplifying a reception signal, a radio frequency output terminal for outputting a reception signal, a switch for switching between a transmission path and a reception path, a filter, and an impedance matching circuit.

The antenna 2 is connected to the external output terminal 92 of the radio frequency circuit 1 and transmits a radio frequency signal output from the radio frequency circuit 1. The antenna 2 may externally receive a radio frequency signal and output the radio frequency signal to the radio frequency circuit 1.

The RFIC 3 is an example of a signal processing circuit for processing a radio frequency signal. The RFIC 3 is connected to the external input terminal 91 of the radio frequency circuit 1. Specifically, the RFIC 3 performs signal processing upon a transmission signal input from the BBIC 4 by, for example, up-conversion and outputs a radio frequency transmission signal generated as a result of the signal processing to a transmission path in the radio frequency circuit 1. The RFIC 3 may perform signal processing upon a radio frequency reception signal input via a reception path in the radio frequency circuit 1 by, for example, down-conversion and output a reception signal as a result of the signal processing to the BBIC 4.

The BBIC 4 is a baseband signal processing circuit for performing signal processing using an intermediate frequency band lower than the frequency of a radio frequency signal transmitted by the radio frequency circuit 1. Examples of a signal processed by the BBIC 4 include an image signal for image display and/or an audio signal for a call through a speaker.

The circuit configuration of the communication device 5 illustrated in FIG. 1 is an example and does not necessarily have to be employed. For example, the communication device 5 does not necessarily have to include the antenna 2 and/or the BBIC 4. The communication device 5 may include the multiple antennas 2.

### 2. Circuit Configuration of Radio Frequency Circuit 1

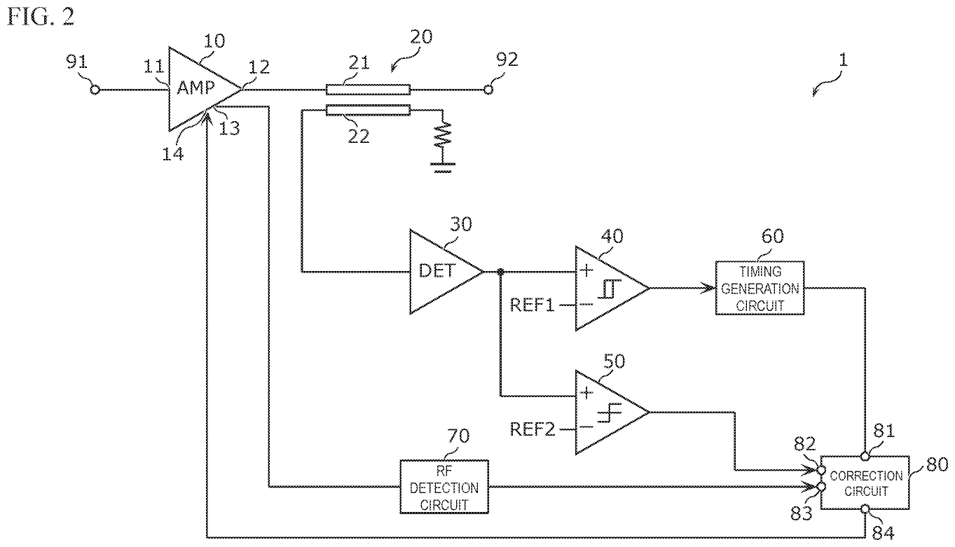

Next, the circuit configuration of the radio frequency circuit 1 according to an embodiment will be described with reference to FIG. 2. FIG. 2 is a diagram illustrating the circuit configuration of the radio frequency circuit 1 according to the present embodiment.

As illustrated in FIG. 2, the radio frequency circuit 1 includes the power amplifier 10, a directional coupler 20, a power detector 30, a first comparator 40, a second comparator 50, a timing generation circuit 60, an RF detection circuit 70, a correction circuit 80, the external input terminal 91, and the external output terminal 92.

The power amplifier 10 is an example of a first circuit for processing a radio frequency signal. Specifically, the power amplifier 10 amplifies a transmission signal.

The power amplifier 10 includes, for example, a bipolar transistor, such as a heterojunction bipolar transistor (HBT). Alternatively, the power amplifier 10 may include a field effect transistor (FET), such as a MOSFET (metal oxide semiconductor field effect transistor). The power amplifier 10 may have a multi-stage configuration of multiple transistors.

The power amplifier 10 includes a radio frequency input terminal 11, a radio frequency output terminal 12, a signal output terminal 13, and a control terminal 14.

The radio frequency input terminal 11 is connected to the external input terminal 91. The radio frequency output terminal 12 is connected to the external output terminal 92 via the directional coupler 20. The radio frequency output terminal 12 is connected to the power detector 30 via the directional coupler 20.

The signal output terminal 13 is connected to the RF detection circuit 70. The signal output terminal 13 is provided at an appropriate position of the power amplifier 10 on the basis of a detection target of the RF detection circuit 70. For example, the signal output terminal 13 may be the same terminal as the radio frequency input terminal 11, the radio frequency output terminal 12, or the control terminal 14.

The control terminal 14 is connected to an output terminal 84 of the correction circuit 80. The control terminal 14 is a terminal into which a control signal for controlling the operation of the power amplifier 10 (e.g., a correction signal for gain compensation) is input.

The power amplifier 10 amplifies a transmission signal input from the radio frequency input terminal 11 and outputs the amplified transmission signal to the external output terminal 92 via a main line 21 of the directional coupler 20. The power amplifier 10 adjusts, for example, a bias and/or a power supply voltage to be supplied to a transistor in response to a control signal input to the control terminal 14.

The directional coupler 20 includes the main line 21 and a sub line 22. The main line 21 and the sub line 22 are electromagnetically coupled to each other. One end of the main line 21 is connected to the radio frequency output terminal 12 of the power amplifier 10. The other end of the main line 21 is connected to the external output terminal 92. The main line 21 transmits a transmission signal amplified by the power amplifier 10.

One end of the sub line 22 is connected to the power detector 30. The other end of the sub line 22 is connected to the ground via a resistor. Since the main line 21 and the sub line 22 are electromagnetically coupled to each other, a coupling signal corresponding to a transmission signal transmitted through the main line 21 flows through the sub line 22. The coupling signal is output from one end of the sub line 22 to the power detector 30.

The resistor connected to the other end of the sub line 22 is a termination resistor. The resistor can absorb and consume the optional component of a signal transmitted through the sub line 22. A capacitor may be connected in addition to the resistor. The resistor may be a variable resistor, and the capacitor may be a variable capacitor.

The power detector 30 is connected to the radio frequency output terminal 12 of the power amplifier 10. Specifically, the power detector 30 is connected to the radio frequency output terminal 12 via the directional coupler 20. The power detector 30 detects the power of a radio frequency signal. In the present embodiment, the power detector 30 indirectly detects the power of a transmission signal output from the power amplifier 10 by detecting a coupling signal output from the sub line 22 in the directional coupler 20. The power detector 30 outputs a voltage signal representing a result of detection of power. For example, the voltage level of a voltage signal corresponds to the magnitude of power of a radio frequency signal. The voltage level of a voltage signal is hereinafter referred to as a “detection voltage”.

The first comparator 40 is connected between the output of the power detector 30 and a clock terminal 81 of the correction circuit 80. In the present embodiment, the first comparator 40 is connected between the output of the power detector 30 and the timing generation circuit 60. The first comparator 40 compares a voltage representing a detection result of the power detector 30 (i.e., a detection voltage) and a reference voltage REF1 with each other. The reference voltage REF1 is an example of a first reference voltage.

The first comparator 40 is, for example, an operational amplifier having a non-inverting input terminal (+), an inverting input terminal (−), and an output terminal. The non-inverting input terminal of the first comparator 40 is connected to the output of the power detector 30, and a voltage signal is input to the non-inverting input terminal from the power detector 30. The inverting input terminal of the first comparator 40 is connected to a reference voltage source (not illustrated), and the reference voltage REF1 is input to the inverting input terminal. The output terminal of the first comparator 40 is connected to the timing generation circuit 60.

The first comparator 40 compares a detection voltage and the reference voltage REF1 with each other and outputs a first signal representing a result of the comparison from the output terminal to the timing generation circuit 60. The first signal representing a result of comparison is, for example, a signal indicating whether a detection voltage is higher or lower than the reference voltage REF1 using two values of a high level and a low level.

The second comparator 50 is connected between the output of the power detector 30 and an enable terminal 82 of the correction circuit 80. The second comparator 50 compares a voltage representing a detection result of the power detector 30 (i.e., a detection voltage) and a reference voltage REF2 with each other. The reference voltage REF2 is an example of a second reference voltage and is higher than the reference voltage REF1.

The second comparator 50 is, for example, an operational amplifier having a non-inverting input terminal (+), an inverting input terminal (−), and an output terminal. The non-inverting input terminal of the second comparator 50 is connected to the output of the power detector 30, and a voltage signal is input from the power detector 30 to the non-inverting input terminal. The inverting input terminal of the second comparator 50 is connected to a reference voltage source (not illustrated), and the reference voltage REF2 is input to the inverting input terminal. The output terminal of the second comparator 50 is connected to the enable terminal 82.

The second comparator 50 compares a detection voltage and the reference voltage REF2 with each other and outputs a second signal representing a result of the comparison from the output terminal to the correction circuit 80. A second signal representing a result of comparison is, for example, a signal indicating whether a detection voltage is higher or lower than the reference voltage REF2 using two values of a high level and a low level.

The timing generation circuit 60 is connected between the output of the first comparator 40 and the clock terminal 81 of the correction circuit 80. The timing generation circuit 60 determines a timing at which the correction circuit 80 performs correction on the basis of a comparison result of the first comparator 40. Here, a “timing” is a concept including not only an instantaneous point in time but also a certain period of time.

The timing generation circuit 60 is, for example, a clock generator. When the first signal indicating that a detection voltage is higher than the reference voltage REF1 is input, the timing generation circuit 60 generates a clock signal and supplies the clock signal to the clock terminal 81 of the correction circuit 80. A timing at which a clock signal is supplied is a timing of correction.

The RF detection circuit 70 is an example of a radio frequency detection circuit and is connected between the power amplifier 10 and an input terminal 83 of the correction circuit 80. Specifically, the RF detection circuit 70 is connected to the signal output terminal 13 of the power amplifier 10.

The RF detection circuit 70 detects the electrical characteristics of a radio frequency signal before and after the amplification of the radio frequency signal performed by the power amplifier 10. Electrical characteristics are, for example, the frequency, power, voltage, current, or impedance of a radio frequency signal. The RF detection circuit 70 may detect two or more electrical characteristics. The RF detection circuit 70 outputs a detection result of electrical characteristics of a radio frequency signal to the input terminal 83 of the correction circuit 80 as a signal for correction.

The correction circuit 80 performs correction upon the power amplifier 10 on the basis of the comparison result of the first comparator 40 and the comparison result of the second comparator 50. Specifically, the correction circuit 80 performs correction at a timing determined by the timing generation circuit 60 on the basis of the comparison result of the second comparator 50.

As illustrated in FIG. 2, the correction circuit 80 includes the clock terminal 81, the enable terminal 82, the input terminal 83, and the output terminal 84.

A clock signal is supplied from the timing generation circuit 60 to the clock terminal 81. A timing at which a clock signal is supplied to the clock terminal 81 is a timing at which correction can be performed. That is, the correction circuit 80 maintains a state in which a correction operation is available when a clock signal is supplied thereto.

A signal representing the comparison result of the second comparator 50 is supplied to the enable terminal 82. The correction circuit 80 determines whether to perform correction on the basis of a signal input to the enable terminal 82. Specifically, the correction circuit 80 performs correction when the second signal indicating that a detection voltage is higher than the reference voltage REF2 is input to the enable terminal 82.

A signal for correction is input to the input terminal 83. Specifically, a signal representing the detection result of the RF detection circuit 70 is input to the input terminal 83 as a signal for correction. A signal for correction is, for example, a signal representing the frequency, power, voltage, current, or impedance of a radio frequency signal.

The correction circuit 80 performs correction on the basis of a signal for correction. Specifically, the correction circuit 80 determines a parameter for correction on the basis of a signal for correction, and outputs a control signal (correction signal) from the output terminal 84 such that the power amplifier 10 is controlled with the determined parameter. A control signal is input to the control terminal 14 of the power amplifier 10.

In the present embodiment, the correction circuit 80 maintains the comparison result of the second comparator 50 input to the enable terminal 82 and the state of a signal for connection input to the input terminal 83 in a period in which a clock signal is supplied to the clock terminal 81. Accordingly, the performance of correction based on a comparison result and details determined after the determination of a parameter used for correction are maintained. That is, the termination of correction during the transmission of a radio frequency signal or the change of a parameter in the middle of correction processing are suppressed.

The power amplifier 10 operates in response to a control signal input thereto. For example, a control signal is a signal for adjusting the gain of the power amplifier 10. The adjustment of a gain is performed by adjusting a bias supplied to the gate or base of an amplification transistor in the power amplifier 10. Alternatively, the adjustment of a gain may be performed by adjusting a power supply voltage supplied to the drain or collector of an amplification transistor in the power amplifier 10.

### 3. Correction Processing

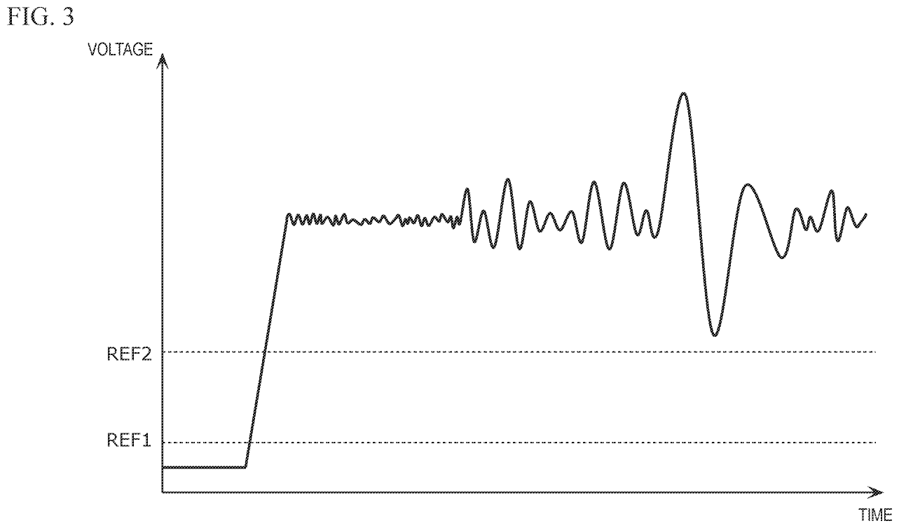

Next, a concrete example of correction processing performed by the correction circuit 80 will be described with reference to FIG. 3. FIG. 3 is a diagram illustrating a radio frequency signal that the radio frequency circuit 1 according to the present embodiment processes and the two reference voltages REF1 and REF2. Referring to FIG. 3, the horizontal axis represents time and the vertical axis represents voltage.

The radio frequency signal illustrated in FIG. 3 is, for example, a voltage signal output form the power detector 30. A radio frequency signal is, for example, a signal compliant with a communication standard, such as Wi-Fi®, LTE (Long Term Evolution), or 5G (5th Generation). For example, a radio frequency signal is a signal in the 1 GHz band, the 2.4 GHz band, or the 5 GHz band, but is not limited thereto.

A radio frequency signal is a signal obtained by modulating a carrier wave using a modulating signal representing predetermined information. In the present embodiment, a radio frequency signal is a transmission signal. As illustrated in FIG. 3, the signal level (voltage level) of a radio frequency signal is higher than a certain level at the time of transmission and changes in accordance with a modulating signal in this period in which the signal level is high.

In the present embodiment, the reference voltage REF1 and the reference voltage REF2 higher than the reference voltage REF1 are set. At the rise of the voltage level of a radio frequency signal, that is, the start of transmission of a radio frequency signal, a detection voltage exceeds the reference voltage REF1. The first comparator 40 outputs the first signal indicating that the detection voltage exceeds the reference voltage REF1. Thus, the first comparator 40 can detect the start of transmission of a radio frequency signal by comparison with the reference voltage REF1.

When the first signal is input, the timing generation circuit 60 generates a clock signal and supplies the clock signal to the clock terminal 81. The correction circuit 80 is therefore brought into a state in which it can perform correction.

When the detection voltage exceeds the reference voltage REF2, the second comparator 50 outputs the second signal indicating that the detection voltage exceeds the reference voltage REF2. When the second signal is input to the enable terminal 82, the correction circuit 80 performs correction on the basis of a signal for correction input from the input terminal 83. Specifically, the correction circuit 80 determines a parameter for correction on the basis of the signal for correction and outputs a control signal based on the determined parameter (correction signal) from the output terminal 84 to the power amplifier 10. As a result, suitable correction such as gain compensation is performed upon the power amplifier 10.

Thus, in the radio frequency circuit 1 according to the present embodiment, the two reference voltages REF1 and REF2 are set and correction is performed on the basis of results of comparison with the two reference voltages REF1 and REF2. Specifically, the radio frequency circuit 1 determines the start of processing (transmission) of a radio frequency signal by comparison with the lower reference voltage REF1 and determines whether the radio frequency signal is a correction target by comparison with the higher reference voltage REF2. By such two-step determination, correction can be appropriately performed upon a radio frequency signal that needs to be corrected at the time of transmission of the radio frequency signal.

The effects of the radio frequency circuit 1 according to the present embodiment will be described below while the problem of a comparative example in which only a single reference voltage is set will be described.

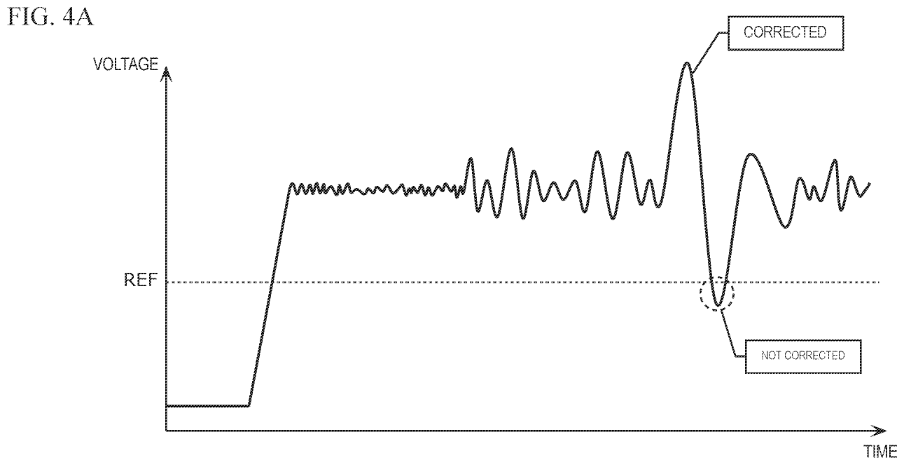

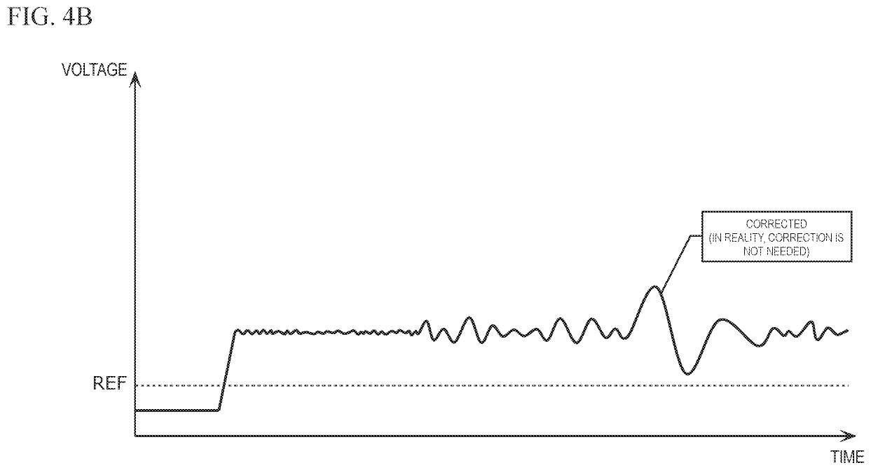

FIGS. 4A and 4B are diagrams for the description of a problem when the number of reference voltages is one. Referring to FIGS. 4A and 4B, the horizontal axis represents time and the vertical axis represents voltage.

FIG. 4A illustrates an exemplary case where the amount of change in radio frequency signal is large and the detection voltage of a radio frequency signal falls below a reference voltage REF. When a detection voltage exceeds the reference voltage REF, the correction of a radio frequency signal is performed. On the other hand, the correction of the radio frequency signal is not performed at a timing at which the detection voltage falls below the reference voltage REF. That is, a correction function is switched between ON and OFF during the transmission of a radio frequency signal.

When the frequency of a modulating signal is low, the turning on and off of a switch may follow. However, the turning on and off of a switch cannot follow with the increase in the frequency of a modulating signal, and correction cannot be performed at an appropriate timing. That is, the real-time performance of correction is reduced or lacked.

In view of this point, it is desired that the correction function not be switched between ON and OFF during the transmission of a radio frequency signal. For this purpose, it is assumed that the reference voltage REF is reduced. However, when the reference voltage REF is reduced, the case may arise as illustrated in FIG. 4B where a radio frequency signal that does not need to be corrected is corrected.

In the radio frequency circuit 1, radio frequency signals in a plurality of communication bands may be processed and the radio frequency signals amplified by the power amplifier 10 have various electrical characteristics. Accordingly, for example, the case may arise where a radio frequency signal with a low detection voltage which does not need to be corrected is corrected.

In the radio frequency circuit 1 according to the present embodiment, the determination of whether correction is performed is not made with the single reference voltage REF but is made in two stages with the two reference voltages REF1 and REF2 of different levels. Accordingly, even if the frequency of a modulating signal is high, correction can be performed with high accuracy. For example, in the case where a gain changes because of a predetermined factor such as a load change, gain compensation can be performed with high accuracy.

In the present embodiment, the timing generation circuit 60 may have a delay function of delaying a timing at which a clock signal is supplied. As illustrated in FIG. 3, it takes a predetermined period of time from the beginning of rise of the voltage level of a radio frequency signal to the end of the rise. If the determination of a parameter for correction starts before the end of rise, an appropriate parameter is not determined in some cases. By causing the timing generation circuit 60 to delay the supply of a clock signal, the start of operation of the correction circuit 80 can be delayed and an appropriate parameter can be determined. The accuracy of correction can therefore be increased.

### 4. Effects, Etc.

As described above, the radio frequency circuit 1 according to the present embodiment includes the first circuit including the radio frequency input terminal 11, the radio frequency output terminal 12, and the control terminal 14, the power detector 30 connected to the radio frequency output terminal 12, the correction circuit 80 including the clock terminal 81, the enable terminal 82, the input terminal 83, and the output terminal 84, the first comparator 40 connected between the output of the power detector 30 and the clock terminal 81, and the second comparator 50 connected between the output of the power detector 30 and the enable terminal 82. The output terminal 84 is connected to the control terminal 14. The reference voltage REF2 of the second comparator 50 is higher than the reference voltage REF1 of the first comparator 40.

The high-performance radio frequency circuit 1 can therefore be provided. Specifically, the radio frequency circuit 1 can determine whether to start the processing (transmission) of a radio frequency signal by comparison with the lower reference voltage REF1 and can determine whether the radio frequency signal is a correction target by comparison with the higher reference voltage REF2. By performing such two-stage determination, the radio frequency circuit 1 can appropriately perform correction such as gain compensation at the time of the processing of a radio frequency signal that needs to be corrected.

For example, the radio frequency circuit 1 further includes the timing generation circuit 60 connected between the output of the first comparator 40 and the clock terminal 81.

For example, a timing at which the processing of the correction circuit 80 starts can therefore be adjusted. Since a parameter for correction can be determined at an appropriate timing, the accuracy of correction can be increased.

For example, the radio frequency circuit 1 further includes the RF detection circuit 70 connected between the first circuit and the input terminal 83.

For example, correction based on the electrical characteristics of a radio frequency signal, such as the frequency, voltage, current, or impedance of the radio frequency signal, can therefore be performed.

For example, the radio frequency circuit 1 further includes the directional coupler 20. The power detector 30 is connected to the radio frequency output terminal 12 via the directional coupler 20.

The power of a radio frequency signal can be detected while the effect on the radio frequency signal propagating through a transmission path is suppressed.

The radio frequency circuit 1 according to the present embodiment includes a first circuit for processing a radio frequency signal, the power detector 30 for detecting power of a radio frequency signal, the first comparator 40 for comparing a voltage representing a detection result of the power detector 30 and the reference voltage REF1 with each other, the second comparator 50 for comparing a voltage representing the detection result of the power detector 30 and the reference voltage REF2 higher than the reference voltage REF1 with each other, and the correction circuit 80 for performing correction upon the first circuit on the basis of a comparison result of the first comparator 40 and a comparison result of the second comparator 50.

The high-performance radio frequency circuit 1 can therefore be provided. Specifically, the radio frequency circuit 1 can determine whether to start the processing (transmission) of a radio frequency signal by comparison with the lower reference voltage REF1 and can determine whether the radio frequency signal is a correction target by comparison with the higher reference voltage REF2. By performing such two-stage determination, the radio frequency circuit 1 can appropriately perform correction such as gain compensation at the time of the processing of a radio frequency signal that needs to be corrected.

For example, the radio frequency circuit 1 further includes the timing generation circuit 60 for determining a timing at which correction is performed on the basis of a comparison result of the first comparator 40. The correction circuit 80 performs correction at a timing determined by the timing generation circuit 60 on the basis of a comparison result of the second comparator 50.

For example, a timing at which the processing of the correction circuit 80 starts can therefore be adjusted. Since a parameter for correction can be determined at an appropriate timing, the accuracy of correction can be increased.

For example, the correction circuit 80 performs correction on the basis further of a detection result of electrical characteristics of a radio frequency signal.

For example, correction based on the electrical characteristics of a radio frequency signal, such as the frequency, voltage, current, or impedance of the radio frequency signal, can therefore be performed.

For example, the first circuit is the power amplifier 10.

Gain compensation can therefore be performed upon the power amplifier 10. For example, the change in gain due to a load change or another factor can be compensated for.

For example, the power amplifier 10 includes a field effect transistor or a bipolar transistor.

By adjusting a bias or a power supply voltage supplied to a transistor, gain compensation can be performed.

The exemplary case has been described in the present embodiment where the correction circuit 80 performs correction (gain compensation) upon the power amplifier 10 disposed on a transmission path, but another case may be employed. For example, the radio frequency circuit 1 may include a low-noise amplifier disposed on a reception path. The correction circuit 80 may perform correction (gain compensation) upon the low-noise amplifier.

### 5. Modifications

Next, modifications of an embodiment will be described. Descriptions will be made below focusing on the difference between the embodiment and the modification, and the description of commonalities between them will be omitted or simplified.

### 5.1. First Modification

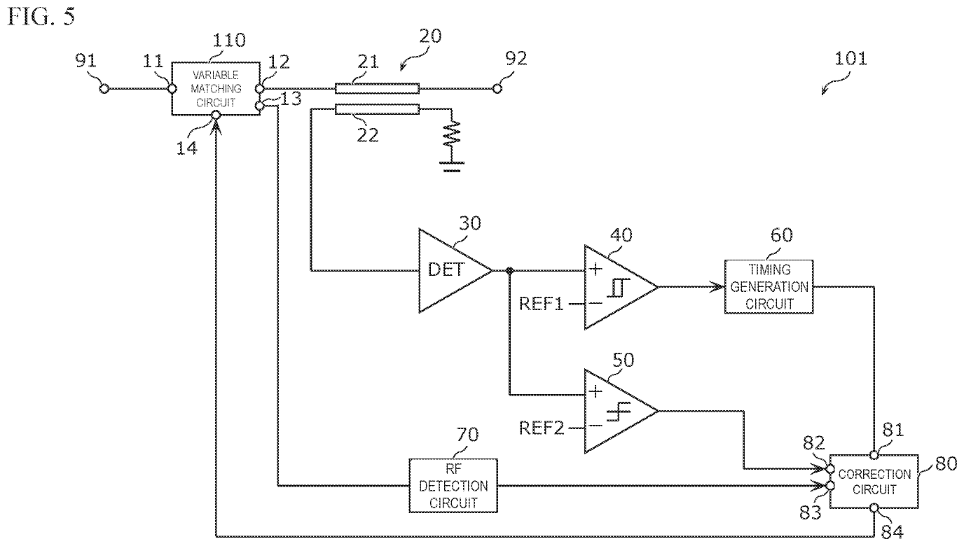

First, a radio frequency circuit 101 according to the first modification will be described with reference to FIG. 5.

FIG. 5 is a diagram illustrating the circuit configuration of the radio frequency circuit 101 according to the present modification. As illustrated in FIG. 5, the radio frequency circuit 101 differs from the radio frequency circuit 1 according to an embodiment in that it includes a variable matching circuit 110 instead of the power amplifier 10.

The variable matching circuit 110 is a matching circuit with a variable impedance. The variable matching circuit 110 is connected to, for example, the input or output of the power amplifier 10 (see FIG. 1). In the case where the power amplifier 10 has a multi-stage configuration of multiple transistors, the variable matching circuit 110 may be disposed between an anterior-stage amplification transistor and a posterior-stage transistor.

The variable matching circuit 110 may be connected to a switch circuit or a filter disposed on a transmission path in the radio frequency circuit 101. The variable matching circuit 110 may be connected to a low-noise amplifier, a switch circuit, or a filter disposed on a reception path in the radio frequency circuit 101.

The variable matching circuit 110 includes a variable inductor and/or a variable capacitor. A variable inductor includes, for example, one or more inductors and one or more switches. A variable capacitor includes, for example, one or more capacitors and one or more switches. The variable matching circuit 110 switches between ON and OFF of each switch in response to a control signal (correction signal) input to the control terminal 14. The variable matching circuit 110 can therefore change an impedance in response to a correction signal.

Thus, in the radio frequency circuit 101 according to the present modification, the first circuit is the variable matching circuit 110.

Accordingly, the impedance of the variable matching circuit 110 can be adjusted in response to the change in the frequency, power, and/or impedance of a radio frequency signal. Since impedance adjustment can be performed in response to the change in the electrical characteristics of a radio frequency signal, a power loss can be reduced and efficiency can be increased.

### 5.2. Second Modification

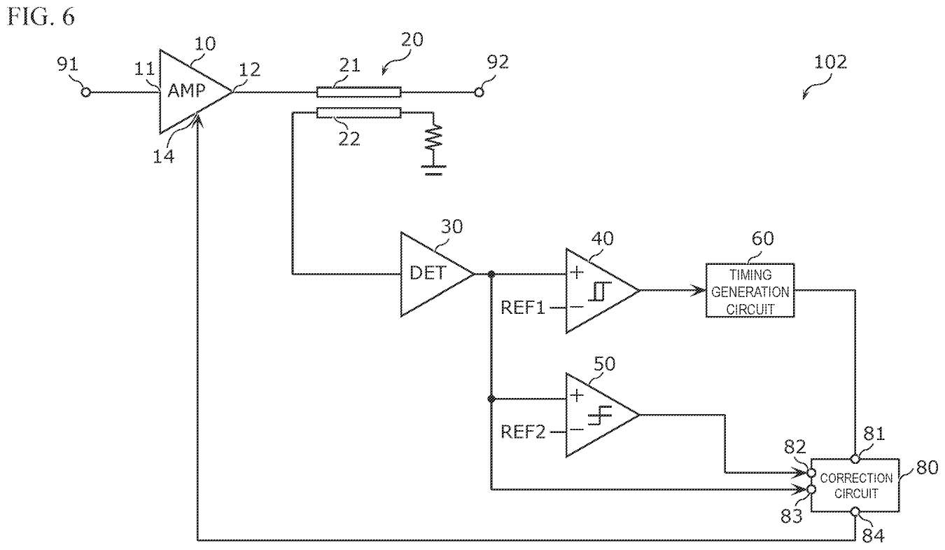

Next, a radio frequency circuit 102 according to the second modification will be described with reference to FIG. 6.

FIG. 6 is a diagram illustrating the circuit configuration of the radio frequency circuit 102 according to the present modification. As illustrated in FIG. 6, the radio frequency circuit 102 differs from the radio frequency circuit 1 according to an embodiment in that it does not include the RF detection circuit 70.

In the present modification, the input terminal 83 of the correction circuit 80 is connected to the output of the power detector 30. That is, a detection result of the power detector 30 is input to the input terminal 83.

The correction circuit 80 can therefore perform correction in accordance with the detection voltage of a radio frequency signal. Since there is no need to provide the RF detection circuit 70, the circuit configuration of the radio frequency circuit 102 can be simplified and the radio frequency circuit 1 can be miniaturized.

### 5.3. Third Modification

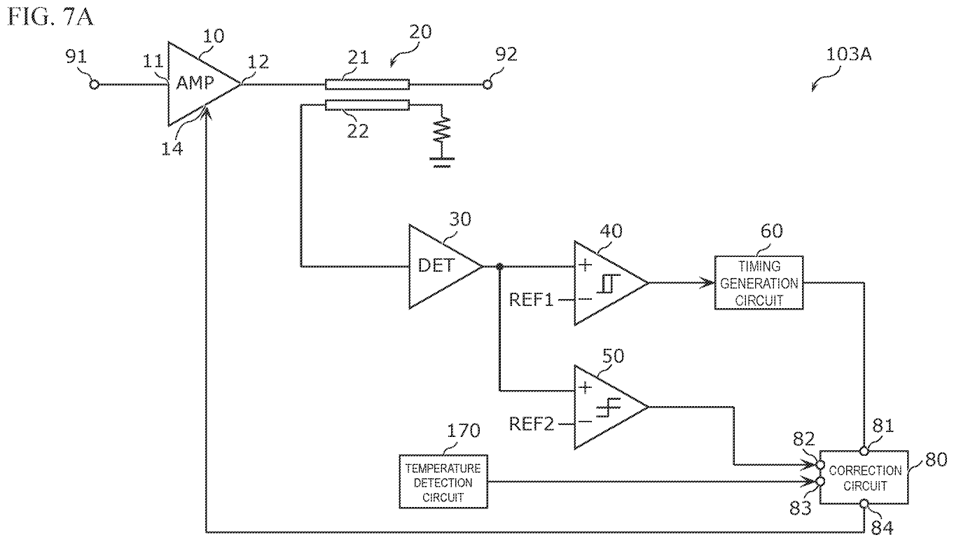

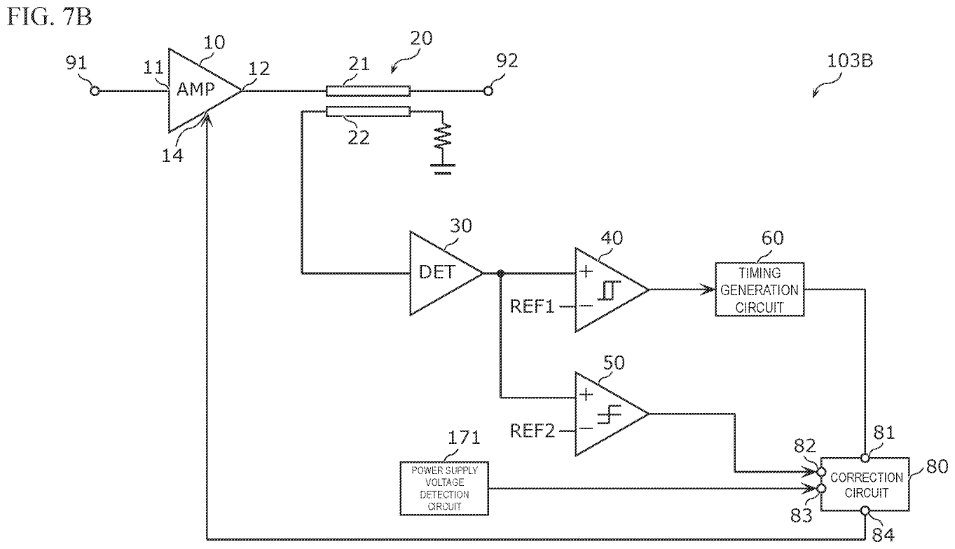

Next, a radio frequency circuit 103A according to the third modification will be described with reference to FIG. 7A.

FIG. 7A is a diagram illustrating the circuit configuration of the radio frequency circuit 103A according to the present modification. As illustrated in FIG. 7A, the radio frequency circuit 103A differs from the radio frequency circuit 1 according to the first embodiment in that it includes a temperature detection circuit 170 instead of the RF detection circuit 70.

The temperature detection circuit 170 detects the temperature of the power amplifier 10. For example, the temperature detection circuit 170 is disposed on a substrate included in the radio frequency circuit 103A on which the power amplifier 10 is disposed. The temperature detection circuit 170 is connected to the input terminal 83 of the correction circuit 80 and outputs a detection result to the input terminal 83.

The correction circuit 80 performs correction on the basis of a temperature detection result input to the input terminal 83. The change in the gain of the power amplifier 10 due to a temperature change can therefore be compensated for. Thus, correction can be performed on the basis of information other than the electrical characteristics of a radio frequency signal.

In the present modification, the temperature detection circuit 170 is an example of a detection circuit for detecting a signal other than a radio frequency signal. A detection circuit included in the radio frequency circuit 103A according to the present modification is not limited to the temperature detection circuit 170.

FIG. 7B is a diagram illustrating the circuit configuration of a radio frequency circuit 103B according to the present modification. As illustrated in FIG. 7B, the radio frequency circuit 103B includes a power supply voltage detection circuit 171 instead of the temperature detection circuit 170.

The power supply voltage detection circuit 171 detects the voltage of a power supply circuit (not illustrated) which is supplied to the radio frequency circuit 103B. For example, the power supply voltage detection circuit 171 detects a power supply voltage supplied to the power amplifier 10. The power supply voltage detection circuit 171 is connected to the input terminal 83 of the correction circuit 80 and outputs a detection result to the input terminal 83.

The correction circuit 80 performs correction on the basis of a power supply voltage detection result input to the input terminal 83. The change in the gain of the power amplifier 10 due to the change in power supply voltage can therefore be compensated for. Thus, correction can be performed on the basis of information other than the electrical characteristics of a radio frequency signal.

### 5.4. Fourth Modification

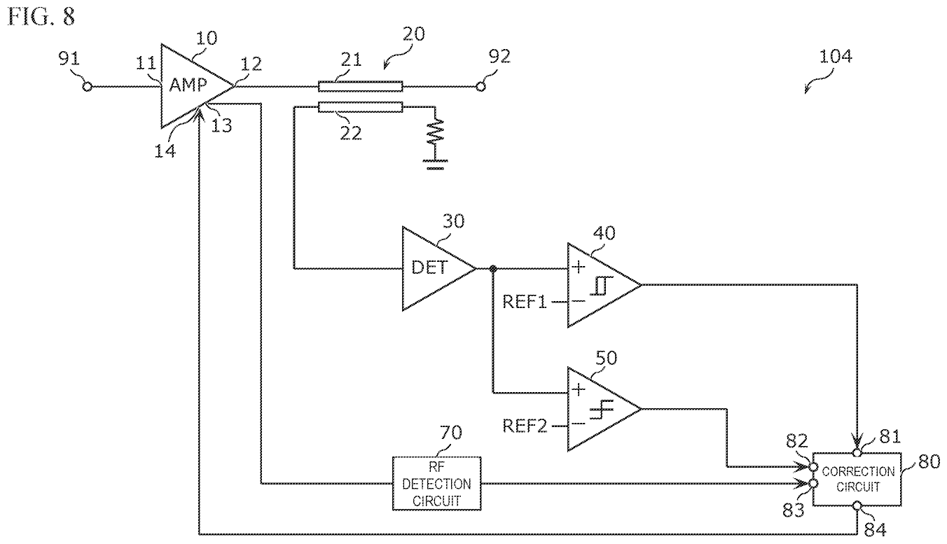

Next, a radio frequency circuit 104 according to the fourth modification will be described with reference to FIG. 8.

FIG. 8 is a diagram illustrating the circuit configuration of the radio frequency circuit 104 according to the present modification. As illustrated in FIG. 8, the radio frequency circuit 104 differs from the radio frequency circuit 1 according to the first embodiment in that it does not include the timing generation circuit 60. In the present modification, the output of the first comparator 40 is directly connected to the clock terminal 81 of the correction circuit 80.

As described above, the timing generation circuit 60 also functions as a delay circuit for compensating for the delay in voltage detection at the time of rise of a radio frequency signal. Accordingly, in the case where the delay in voltage detection is not problem, the timing generation circuit 60 does not necessarily have to be provided like in the radio frequency circuit 104 according to the present modification.

In the present modification, a comparison result of the first comparator 40 is input to the clock terminal 81 of the correction circuit 80. When a detection voltage is higher than the reference voltage REF1, the correction circuit 80 is brought into a state in which correction can be performed. When a detection voltage is higher than the reference voltage REF2, the correction circuit 80 may perform correction.

In the second to fourth modifications, each of the radio frequency circuits 102 to 104 includes the power amplifier 10, but does not necessarily have to include the power amplifier 10. Each of the radio frequency circuits 102 to 104 may include the variable matching circuit 110 like in the first modification.

### Others

A radio frequency circuit according to the present disclosure has been described with reference to the above-described embodiment and the like, but the present disclosure is not limited to the above embodiment.

For example, at least one of the reference voltage REF1 or REF2 may be variable. For example, the reference voltage REF2 may be variable on the basis of the electrical characteristics of a radio frequency signal. The possibility that the correction function is turned on or off in the middle of the transmission of a radio frequency signal can be further reduced.

Modes realized by making various modifications supposed by those skilled in the art to each embodiment and modes realized by optionally combining the constituent elements and the functions in each embodiment without necessarily departing from the scope of the present disclosure are also included in the present disclosure.

### INDUSTRIAL APPLICABILITY

For example, the present disclosure is widely applicable for use in a communication device (e.g., a mobile phone) as a radio frequency circuit disposed in a multiband front-end portion.

### REFERENCE SIGNS LIST

1, 101, 102, 103A, 103B, and 104 radio frequency circuit
2 antenna
3 RFIC
4 BBIC
5 communication device
10 power amplifier
11 radio frequency input terminal
12 radio frequency output terminal
13 signal output terminal
14 control terminal
20 directional coupler
21 main line
22 sub line
30 power detector
40 first comparator
50 second comparator
60 timing generation circuit
70 RF detection circuit
80 correction circuit
81 clock terminal
82 enable terminal
83 input terminal
84 output terminal
91 external input terminal
92 external output terminal
110 variable matching circuit
170 temperature detection circuit
171 power supply voltage detection circuit

1. A radio frequency circuit comprising:
a first circuit having a radio frequency input terminal, a radio frequency output terminal, and a control terminal;
a power detector connected to the radio frequency output terminal;
a correction circuit having a clock terminal, an enable terminal, an input terminal, and an output terminal;
a first comparator connected between an output of the power detector and the clock terminal; and
a second comparator connected between an output of the power detector and the enable terminal,
wherein the output terminal is connected to the control terminal, and
wherein a reference voltage of the second comparator is greater than that of the first comparator.

2. The radio frequency circuit according to claim 1, further comprising a timing generation circuit connected between an output of the first comparator and the clock terminal.

3. The radio frequency circuit according to claim 1, further comprising a radio frequency detection circuit connected between the first circuit and the input terminal.

4. The radio frequency circuit according to claim 1, wherein the input terminal is connected to an output of the power detector.

5. The radio frequency circuit according to claim 1, further comprising a temperature detection circuit connected to the input terminal.

6. The radio frequency circuit according to claim 1, further comprising a power supply voltage detection circuit connected to the input terminal.

7. The radio frequency circuit according to claim 1, further comprising a directional coupler,
wherein the power detector is connected to the radio frequency output terminal via the directional coupler.

8. A radio frequency circuit comprising:
a first circuit configured to process a radio frequency signal;
a power detector configured to detect a power of the radio frequency signal;
a first comparator configured to compare a first reference voltage with a voltage representing a detection result of the power detector;
a second comparator configured to compare a second reference voltage with a voltage representing a detection result of the power detector, the second reference voltage being greater than the first reference voltage; and
a correction circuit configured to perform a correction on the first circuit based on a comparison result of the first comparator and a comparison result of the second comparator.

9. The radio frequency circuit according to claim 8, further comprising a timing generation circuit configured to determine a timing at which the correction is performed based on a comparison result of the first comparator,
wherein the correction circuit is configured to perform the correction at the determined timing based on a comparison result of the second comparator.

10. The radio frequency circuit according to claim 8, wherein the correction circuit is configured to perform the correction based further on a detection result of electrical characteristics of the radio frequency signal.

11. The radio frequency circuit according to claim 1, wherein the first circuit is a power amplifier.

12. The radio frequency circuit according to claim 8, wherein the first circuit is a power amplifier.

13. The radio frequency circuit according to claim 11, wherein the power amplifier comprises a field effect transistor or a bipolar transistor.

14. The radio frequency circuit according to claim 12, wherein the power amplifier comprises a field effect transistor or a bipolar transistor.

15. The radio frequency circuit according to claim 1, wherein the first circuit is a variable matching circuit.

16. The radio frequency circuit according to claim 8, wherein the first circuit is a variable matching circuit.
